(19) United States
(12) Patent Application Publication
(10) Pub. No.: US 2005/0269906 A1
(43) Pub. Date: Dec. 8, 2005

(54) Electro-active actuator

(75) Inventors: James Allan, Risby (GB); David Henry Pearce, Moseley (GB); Richard Topliss, Trumpington (GB)

Correspondence Address: NIXON & VANDERHYE, PC, 901 NORTH GLEBE ROAD, 11TH FLOOR, ARLINGTON, VA, 22203, US

(73) Assignee: 1... Limited, Cambridge (GB)

(21) Appl. No.: 10/535,497

(22) PCT Filed: Nov. 11, 2003
(86) PCT No.: PCT/GB03/04862

§ 371 Date: Aug. 2, 2005

(30) Foreign Application Priority Data
Nov. 19, 2002 (GB) 0226846.4
Dec. 24, 2002 (GB) 0229927.9
Mar. 28, 2003 (GB) 0307160.2
May 21, 2003 (GB) 0311676.1

(51) Int. Cl. H01L 41/04

(52) U.S. Cl. 310/332

(57) ABSTRACT

An electro-active actuator having a bender construction comprising layers of electro-active material and electrode layers for activation of the electro-active material, the layers of electro-active material being shaped to extend continuously along at least one curved portion and at least one substantially flat portion arranged with electrical terminals for electrical connection to the electrode layers.

This invention relates to electro-active actuators. More particularly, it relates to elements of electro-active material comprising curved and non-curved (flat) portions.

Electro-active materials are materials that deform or change their dimensions in response to applied electrical conditions or, vice versa, have electrical properties that change in response to applied mechanical forces. The best-known and most used type of electro-active material is piezoelectric material, but other types of electro-active material include electrostrictive and piezoresistive material.

Many devices that make use of electro-active materials are known. The simplest piezoelectric device is a block of pre-poled, i.e., pre-oriented, piezoelectric material activated in an expansion-contraction mode by applying an activation voltage in direction of the poling.

Electro-active effects are extremely small, e.g. in the order of 1 nm/V, so that the change in dimensions is relatively small and requires high voltages. Therefore, more complicated electro-active structures, such as stacks, unimorph or bimorph benders, recurved benders, corrugated benders, spiral or helical designs, have been developed to achieve larger displacements.

Benders, stacks, tubes and other electro-active actuators are employed in a wide array of engineering systems, ranging from micro-positioning applications and acoustic wave processing to printing applications. Generally, actuators are used in such applications to generate force and effect displacement, for example, to move levers or other force transmitting devices, pistons or diaphragms, to accurately position components, or to enable similar system functions. Actuators employed for such functions are typically designed to provide a desired displacement or stroke over which a desired force is delivered to a given load.

Depending upon design, electro-active actuators can generate rotational or translational displacements or combinations of both movements. Curved actuators capable of such displacements are known.

A curved actuator in the form of a flat ceramic bender curved into an almost tubular shape is described in the commonly-owned published international patent application WO-03/001841, which is incorporated herein by reference. The curved actuator forms part of a loudspeaker, in which the actuator is mounted on a support and coupled to an area-extensive section of the case of the device, which section of the case acts as the sound generating element of the loudspeaker. In embodiments illustrated therein the actuator acts upon an edge of the sound generating element, the rotational displacement of the actuator being transmitted to rotational displacement of the sound generating element through the coupling. In cross-section, the actuator appears as a portion of a circle or the shape of a letter C.

Other curved actuators capable of comparably large translation displacements are described in the commonly-owned published international patent application WO-0147041, which is incorporated herein by reference, and by D. H. Pearce et al in: Sensors and Actuators A 100 (2002), 281-286. These actuators are helical structures of coiled piezoelectric bender tape. Such twice-coiled or “super-helical” devices are found to easily exhibit displacement in the order of millimetres on an active length of the order of centimetres.

These structures just described are ceramic devices of complex curved shape. The brittleness of the material makes handling and mounting such actuators a slow and delicate task.

For many applications, it becomes necessary to connect and attach these actuators in such a way that the mechanical and electrical connections to the actuator are robust and capable of creating strain within the actuator or displacing or forcing the system, and to couple this strain, motion or force to the object which is to be controlled.

In a typical application, a piezoelectric element is bonded to a structure in a complex sequence of steps. The surface of the structure is first machined so that one or more channels are created to carry electrical leads needed to connect to the piezoelectric element. Alternatively, instead of machining channels, two different epoxies may be used to make both the mechanical and the electrical contacts. In this alternative approach, a conductive epoxy is spotted, i.e., applied locally to form conductors, and a structural epoxy is applied to the rest of the structure, bonding the piezoelectric element to the structure. The whole structure may then be covered with a protective coating.

During all of these steps there is a risk of damaging and breaking the electro-active structure. This problem is addressed in many published documents relating to the connection of piezoelectric devices to board, substrates and the like, including the U.S. Pat. Nos. 2,877,363; 4,240,002; 4,404,489; 5,404,067; 5,622,748 and 6,420,819.

However, none of the known solutions relate to curved electro-active devices, particularly complex shaped devices such as the C-shaped or super-helical actuators referred to above.

The curved devices described above provide predominantly rotational or translational displacements according to design. While satisfactory for many applications, deviations from the dominant rotational or translational motion may limit the applicability of the actuators in some applications. For example, the displacement of the super-helical actuators may deviate from the desired straight line motion and may also include some rotation, which may limit the applicability of super-helical devices in certain technical fields, such as loudspeaker drive units or lens motors, where strict linearity is a preferable requirement. Similarly, the displacement of the C-shaped curved actuators is predominantly rotary but includes some element of translation. In some applications, it may be desirable to modify the motion to enhance either the rotary or the translational part.

According to an aspect of the invention, there is provided an electro-active actuator having a bender construction comprising layers of electro-active material and electrode layers for activation of the electro-active material, the layers of electro-active material being shaped to extend continuously along at least one curved portion and at least one substantially flat portion arranged with electrical terminals for electrical connection to the electrode layers.

According to a further aspect of the present invention, there is provided an electro-active actuator comprising a permanently curved portion of electro-active material with at least one essentially flat portion, wherein a curved end of said actuator extends into said flat portion.

According to a further aspect of the present invention, there is provided an electro-active actuator having a bender construction comprising layers of electro-active material and electrode layers for activation of the electro-active material, the layers of electro-active material being shaped to extend continuously along at least one curved portion and at least one substantially flat portion.

The flat part facilitates handling of the actuator during manufacture and simplifies mounting the actuator and providing electrical connections. Further, the flat part may modify the motion of the actuator, particularly the relative proportions of translation and rotation. Consequently, the present invention is capable of providing curved electro-active structures, possibly with complex curves, that are easier to handle in post-firing, mounting and packaging operations and that are easier to manufacture.

In a first type of embodiment, the curved portions are curved helically. This type of embodiment will be referred to hereinafter as the helical type. At the end of such helically wound portions the actuator may have a nominally circular cross-section with the axis of the helix as center. The flat portion projects preferably tangentially to that circle, but in other embodiments the tab may bend to form an angle with a tangent to the circle. Alternatively, the flat portion may be formed to project into a direction parallel to the axis of the helix.

In a particularly preferred embodiment the axis of the helical portions of the actuator are curved to form a twice coiled or super-helical actuator.

The length of the flat portion is preferably equal or larger than the outer diameter of the curved actuator. Where the curvature changes, a nominal outer diameter can be defined by using the radius of curvature in the curved portion from which the flat terminal projects.

In a preferred embodiment, the flat portion provides contact terminals for the electrodes of the piezoelectric actuator. Most preferably electrical contacts can be made to operating electrodes, i.e., electrodes used during the activation of the device but not necessarily during poling, from a single exposed surface of the tab. Alternatively, or in addition, electrical contacts may be made via the exposed edges of the tab. For this purpose, electrically conductive layers are either wrapped around part of the tab or, alternatively, the tab includes openings or covered electrodes.

In a further embodiment, the present invention provides a loudspeaker for a possibly portable electronic device such as a mobile phone which comprises a support on which is mounted one or more electro-active actuators, which is in turn coupled to an area-extensive section of the case of the device, which section of the case acts as the sound generating element of the loudspeaker, wherein the actuator or actuators include a curved section and at least one flat section.

In a second type of embodiment, there is a single curved portion curving around an axis and arranged, on actuation, to bend around the axis, and at least one flat portion extending away from the axis. This type of embodiment will be referred to as the Q-type, although merely for ease of reference and without implying any limitation as regards the shape of the actuator.

According to a further aspect of the present invention, there is provided an electro-active actuator having a bender construction comprising layers of electro-active material and electrode layers for activation of the electro-active material, the layers of electro-active material being shaped to extend continuously along at least one curved portion curved around an axis and arranged, on actuation, to bend around the axis, and along at least one substantially flat portion extending away from the axis.

According to a further aspect of the present invention, there is provided a ceramic actuator comprising a first curved section extending radially into a second, essentially flat section.

In such a type of embodiment, the curved section of the actuator may have a hollow cylindrical shape, with one sector extending along the longitudinal axis of the cylinder being removed. Hence a cross-section perpendicular to the longitudinal axis of the curved part is a section of a circle or in other words C-shaped. The flat part also extends longitudinally, the line connecting the curved and flat parts being a longitudinal line. A perpendicular cross-section through flat and curved sections of the actuator thus resembles a flat-lying question mark or cidilla, hereinafter referred to as an actuator of the Q-type. Alternatively, there may be two flat parts, resembling the Greek letter Ω in cross section.

The flat portions facilitate the mounting of the ceramic actuator, for example on to a support structure or on to the object which the actuator is designed to move.

However, an additional advantage is seen in providing a curved actuator that has sections at which the curvature of the material changes from inward bowing (concave) to flat or outward bowing (convex).

In a third type of embodiment, there is a single curved portion and two flat portions extending tangentially from opposite ends of the curved portion, at least one of which is arranged with said electrical terminals for electrical connection to the electrode layers.

According to a further aspect of the present invention, there is provided an electro-active actuator having a bender construction comprising layers of electro-active material and electrode layers for activation of the electro-active material, the layers of electro-active material being shaped to extend continuously along a curved portion and two flat portions extending tangentially from opposite ends of the curved portion.

According to a further aspect of the present invention, there is provided a ceramic actuator comprising an arcuate middle section extending tangentially into two essentially straight end sections

As this type of embodiment can have a similar shape to the letter “U”, it is hereinafter referred to as the U-type, although merely for ease of reference and without implying any limitation as regards the shape of the actuator.

The U-type actuator is preferably cast or formed from one sheet of ceramic precursor material, such as “green tape”. However at least every second of the electrodes required to pole or drive the actuator is discontinuous at the borders between adjacent sections. More preferably, both linear sections are electroded and poled in an essentially identical manner, whilst the center electrode is electroded and poled differently from the other sections.

In a preferred embodiment the length of the curved portion equals substantially the combined length of the straight portions measured in tangential direction. The length referred to is the length of the active, i.e., electroded segment of a section, discounting other passive parts of the sections.

According to a further aspect of this embodiment, there is provided a method of manufacturing ceramic actuators comprising the step of preparing a three layer pre-cursor sheet with a continuous center electrode and two discontinuous outer electrodes with layers of pre-cursor electro active material between adjacent electrode layers.

The discontinuous electrodes are preferably separated by non-conductive gaps at locations that correspond to the transition zones between the sections to be formed at a later forming step, thus being separated into two end and one middle segment.

In a preferred variant of the method, an electrically conducting path is established between the end sections of one discontinuous electrode to the middle section of the other discontinuous electrode.

In a further preferred embodiment of the method, the pre-cursor sheet is pressed in a mold and subsequently dried and sintered at elevated temperatures to render the pre-cursor material into electro-active material and to give the actuator the desired shape.

According to another aspect of the invention the actuator is used to drive a sound generating element in a portable device, preferably connected to a panel type diaphragm. The actuator is preferably mounted with one extended end section along an edge of the diaphragm with the opposite end being mounted on the housing of the device.

In a fourth type of embodiment, the curved portion forms a helix arranged, on actuation, to bend around the axis of the helix, which helix is itself curved to have two sections of opposite curvature with rotational symmetry about the point between the two sections.

According to a further aspect of the present invention, there is provided an electro-active device having a continuous electro-active member extending along a minor axis which is curved, the continuous electro-active member curving around the minor axis and arranged with electrodes to bend, on activation, around the minor axis, thereby to twist around the minor axis concomitantly with relative displacement of portions of the device out of the plane of the curve, wherein the minor axis follows a curve having two sections of opposite curvature with rotational symmetry about the point between the two sections.

According to a further aspect of the present invention, there is provided an electro-active actuator adapted to move objects in a straight line, said actuator having at least one group of coupled actuator sections with each of said sections having a structure of electro-active material extending around a minor axis which is permanently curved and wherein the structure of electro-active material includes successive electro-active portions having electrodes to bend, when activated, around the minor axis, and said sections being coupled by a joint element and arranged in a rotational symmetry about said joint element.

This type of actuator is hereinafter referred to the S-type, although merely for ease of reference and without implying any limitation as regards the shape of the actuator.

In the hereinafter described embodiments, the super-helical sections have a structure of electro-active material extending around a minor axis which is permanently curved and wherein the structure of electro-active material includes successive electro-active portions having electrodes to bend, when activated, around the minor axis. A device according to the present invention includes at least two curved sections, eg two twice coiled or super-helical sections, coupled by a joint point or section at which the curvature of the minor axis changes from inward bowing (concave) to outward bowing (convex). In a more mathematical description, the curvature of the minor axis changes its sign when applying the right hand rule to determine the orientation of the curvature along the minor axis from one end of the device to the other.

By virtue of the rotational symmetry, deviations from a straight linear motion of moving ends of the device balance each other out, and so cancel each other. To do this effectively the sections may be substantially identical and driven by substantially identical control signals or voltages. Substantially identical means the devices have the displacement versus applied voltage properties so as to not hamper each other's straight-line motion but being capable of balancing out other components of the displacement, notwithstanding immaterial differences or inadvertent variations due to manufacturing tolerances or the like.

In a preferred embodiment the two curved sections are formed from a continuous tape. In a variant of this embodiment the joint section is a small portion of the tape and the device has thus the form of the letter “S”.

Alternatively the joint section may be a coupling element or joint section providing connection points to two or more essentially identical sections. To balance each other out, the two or more identical sections are preferably arranged into groups with a rotational symmetry about an axis through the coupling element. These groups could be pairs or triplets or any higher-order arrangement of essentially identical electro-active sections. Two or more groups of section that are internally balanced out, may be arranged in different spatial orientations, for example such that the plane of a first balanced group is perpendicular to a second of such balanced group.

By making the coupling element or joint section flexible in the desired direction of motion but stiff in other directions, the maximum useable linear displacement of the jointed two sections may be increased.

In a particularly preferred embodiment the number and the radius of windings around the minor axis are chosen such that the joint section and the two unconnected ends are located at opposite circumferential positions (with respect to the minor circumference). This orientation facilitates the mounting and use of the device on a flat surface such as a printed circuit board (PCB).

The present invention is particularly advantageous for use as loudspeaker drive unit or lens drive system.

These and other aspects of inventions will be apparent from the following detailed description of non-limitative examples making reference to the following drawings, in which:

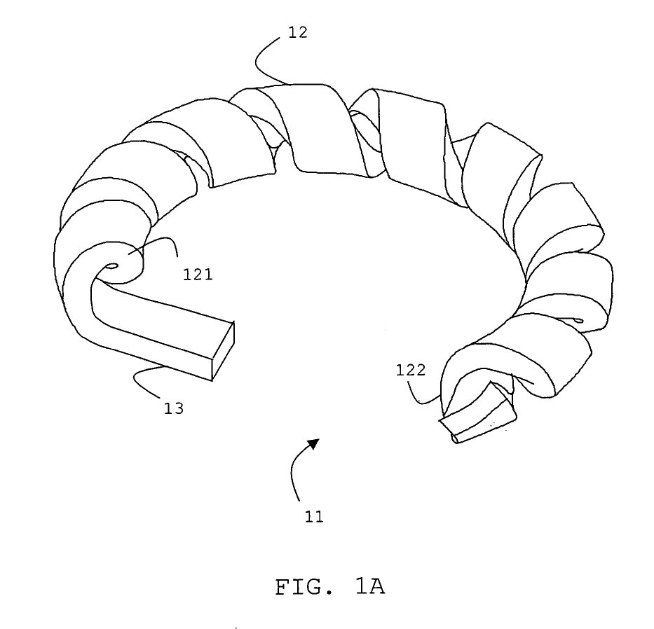

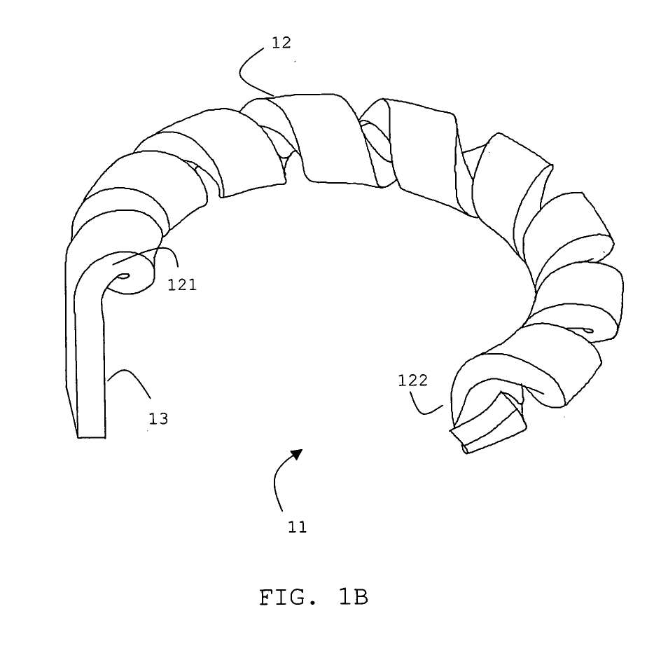

FIG. 1A is a perspective view of an actuator which is a helical type of embodiment of the present invention;

FIG. 1B is a perspective view of another actuator which is a helical type of embodiment of the present invention;

FIG. 1C is a perspective view of another actuator which is a helical type of embodiment of the present invention;

FIG. 1D is a perspective view of another actuator which is a helical type of embodiment of the present invention;

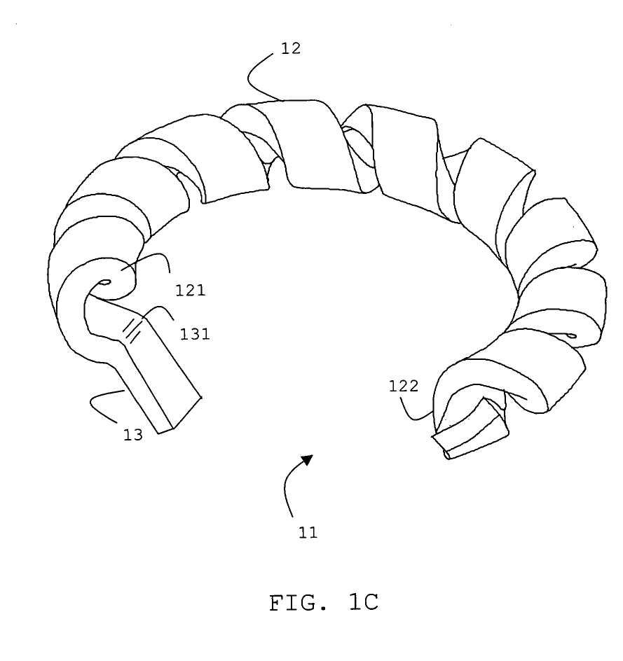

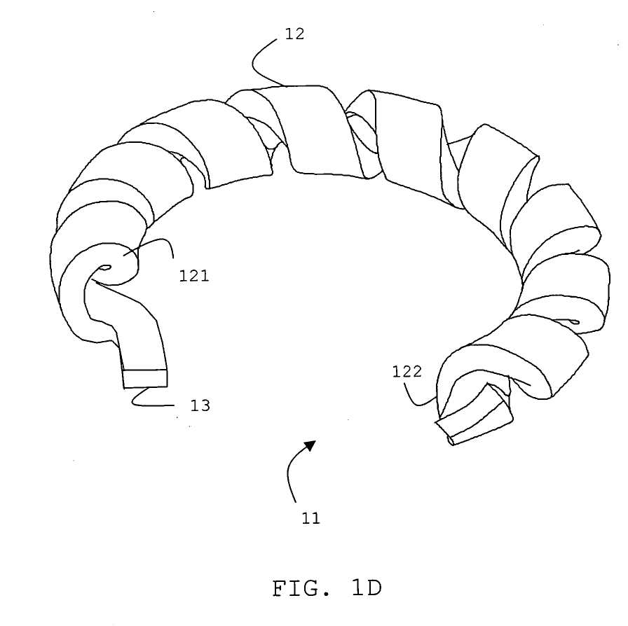

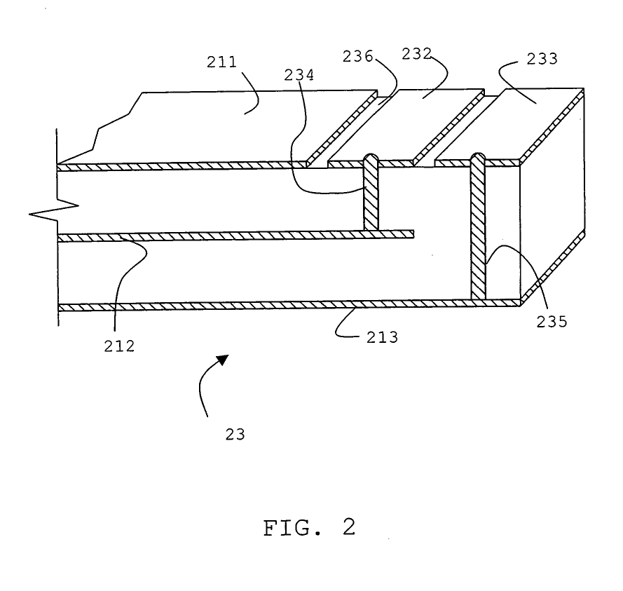

FIG. 2 shows a schematic cross-sectional view showing the flat end portion of the actuators of FIGS. 1A to 1D and illustrating the bender construction;

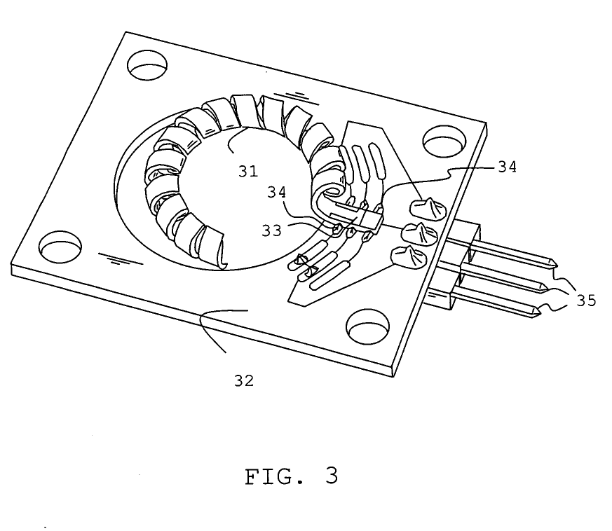

FIG. 3 is a perspective view of an actuator which is a helical type of embodiment of the present invention mounted on a circuit board;

FIG. 4A is a perspective top view of an actuator of the Q-type in accordance with an example of the invention;

FIG. 4B shows a cross section through the actuator of FIG. 4A;

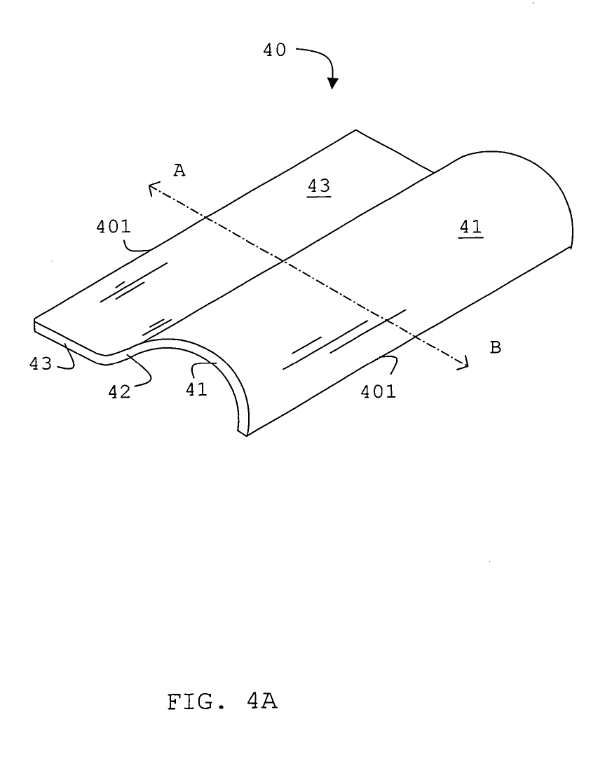

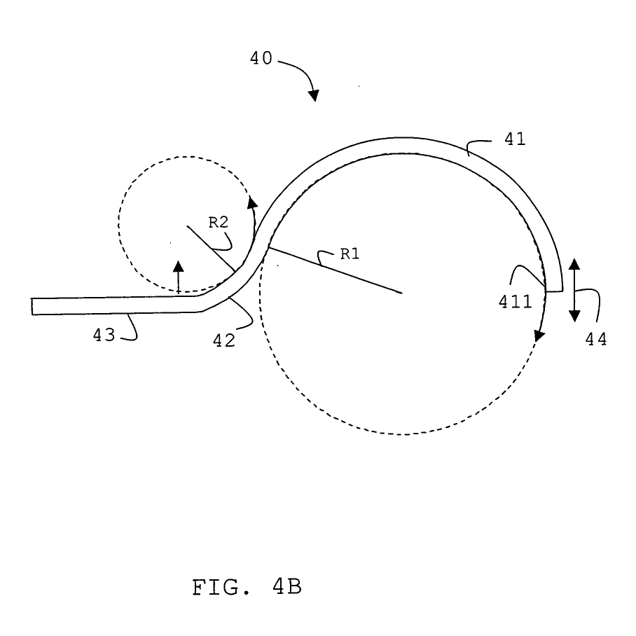

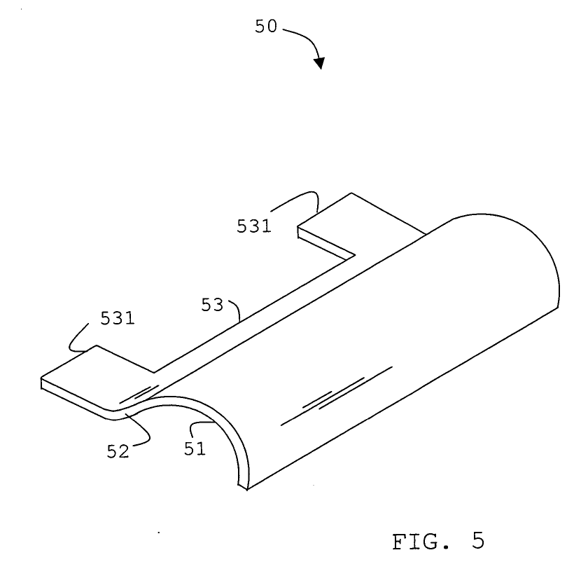

FIG. 5 is a perspective top view of a variant of the Q-type actuator;

FIG. 6 is a perspective top view of another variant of the Q-type actuator;

FIGS. 7A,B illustrate a loudspeaker driven by an actuator as shown in FIG. 4A;

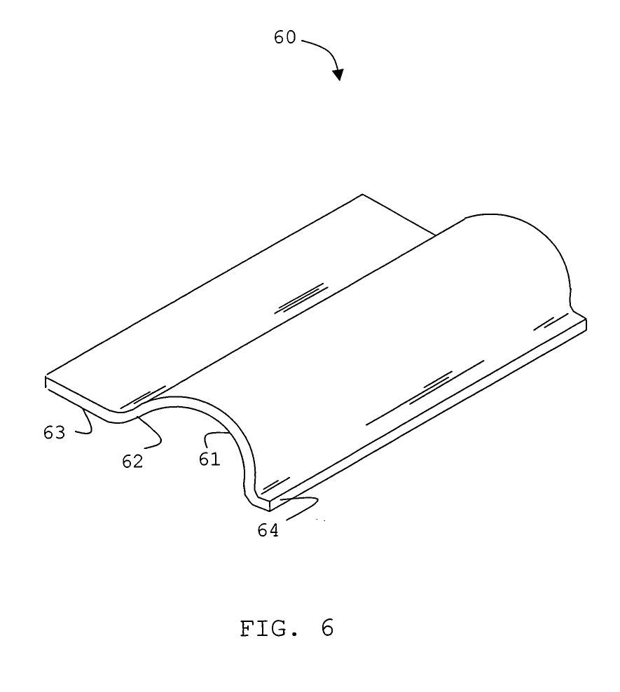

FIG. 8A is a perspective top view of an actuator of the U-type in accordance with an example of the invention;

FIG. 8B shows a top view on the bottom face of the actuator of FIG. 8A;

FIG. 8C shows a cross section through the actuator of FIG. 8A;

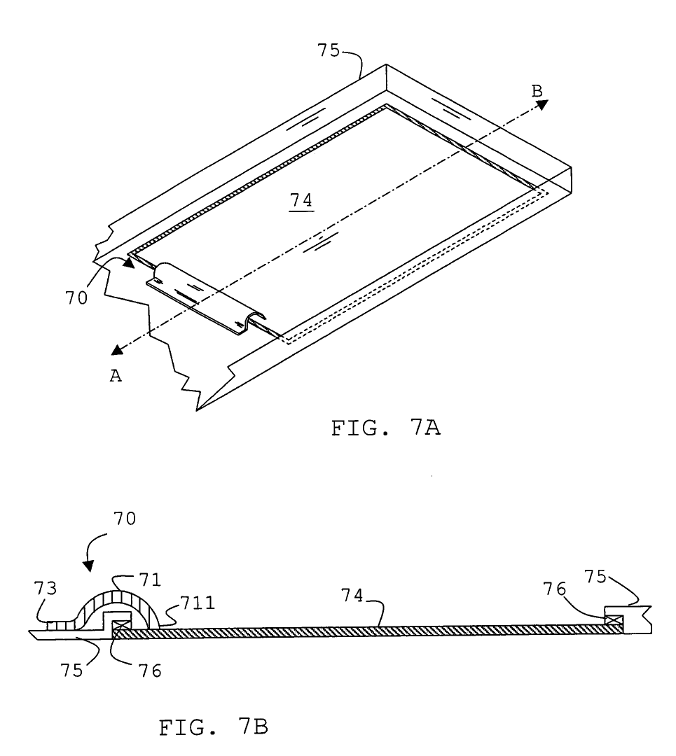

FIG. 9 illustrates the bending deformation of the actuator of FIG. 8;

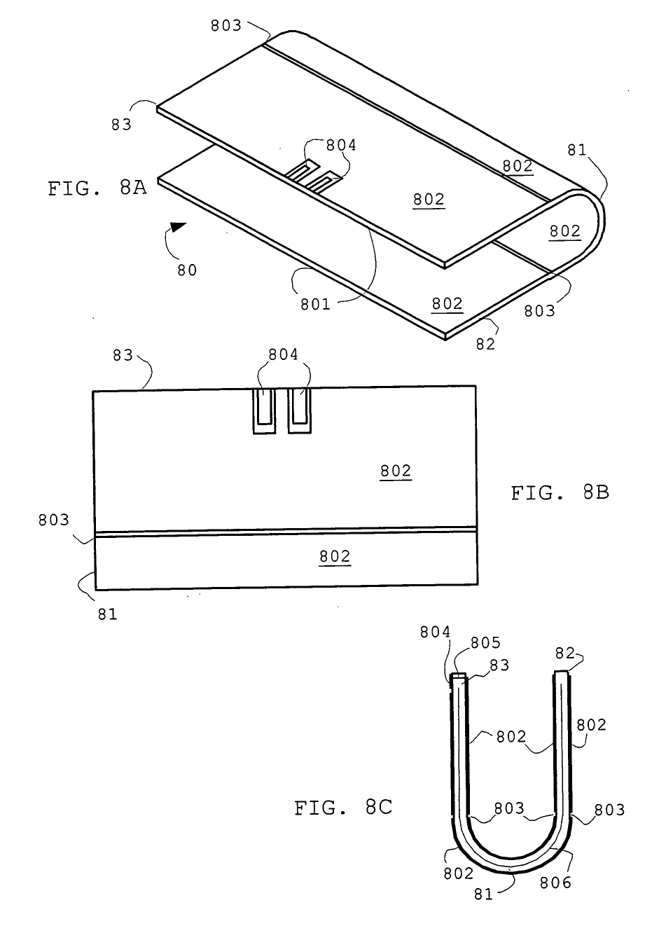

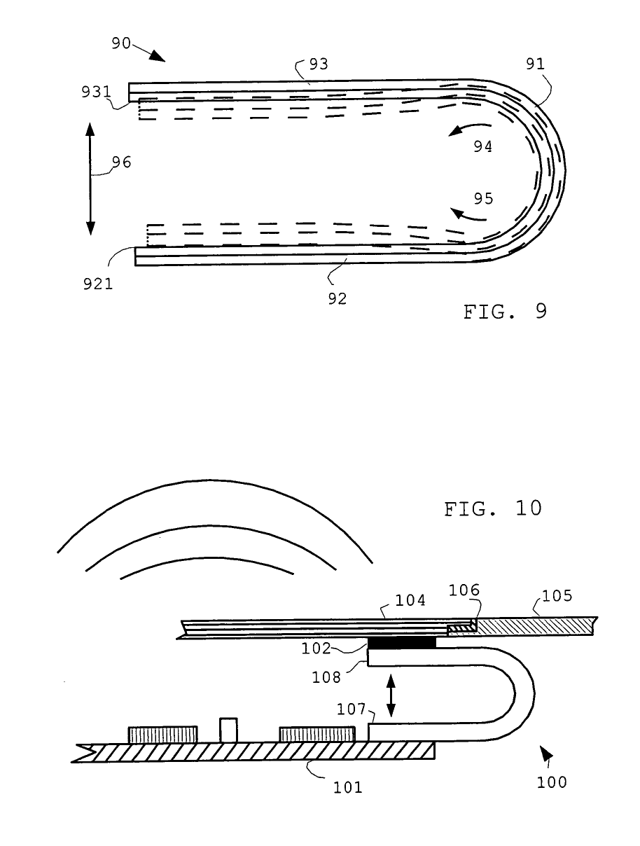

FIG. 10 illustrates a loudspeaker driven by an actuator as shown in FIG. 8;

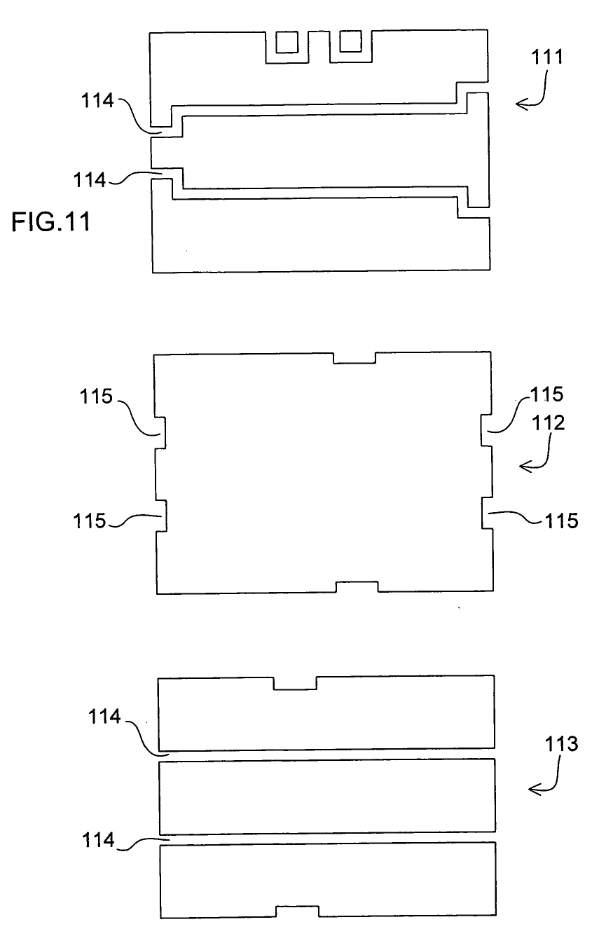

FIG. 11 shows electrode layouts for use in a manufacturing process for an actuator of the U-type in accordance with the invention;

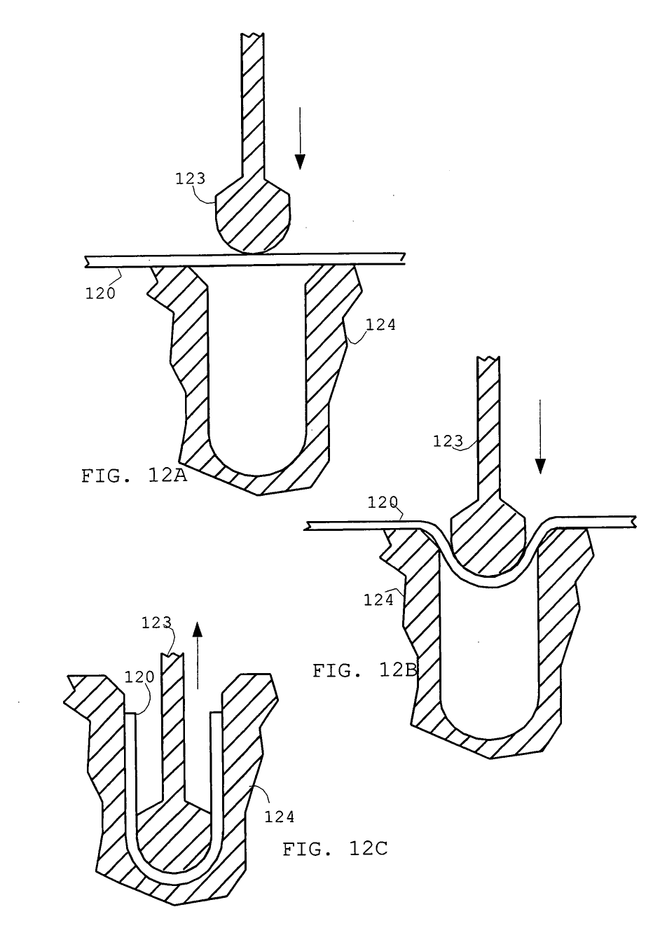

FIGS. 12A-C illustrate a tape forming process for use in a manufacturing process for a U-type actuator in accordance with the invention;

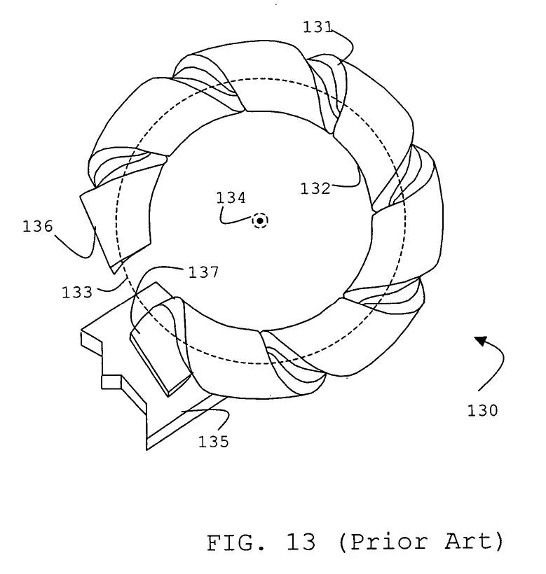

FIG. 13 is a perspective view of a twice-coiled actuator as known;

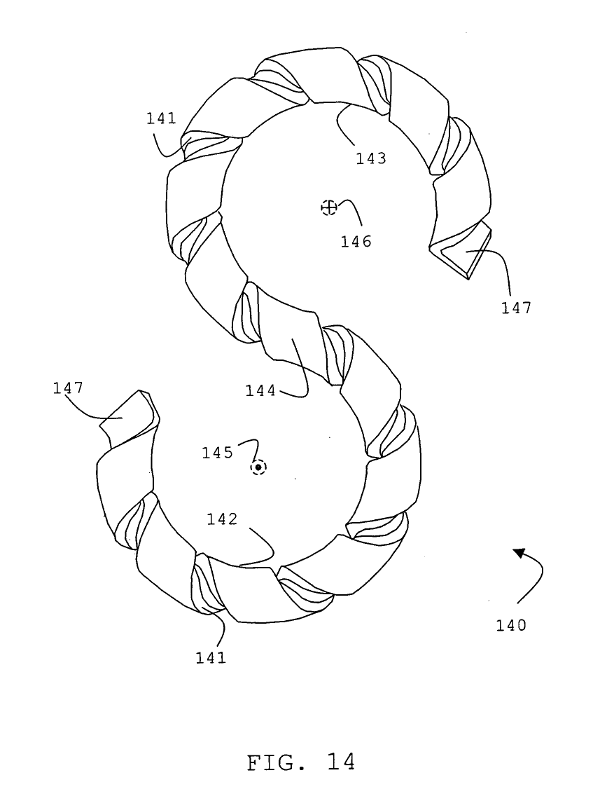

FIG. 14 shows an example of an actuator of the S-type in accordance with the present invention;

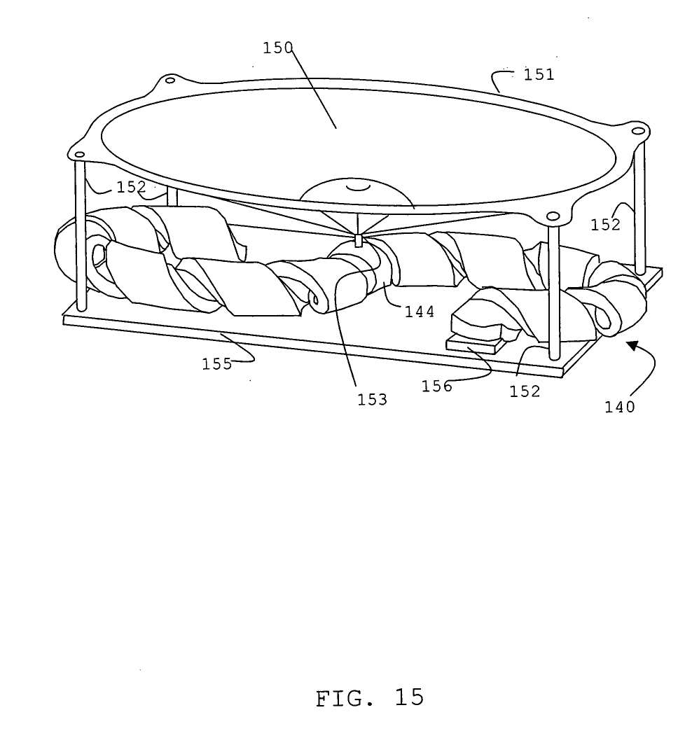

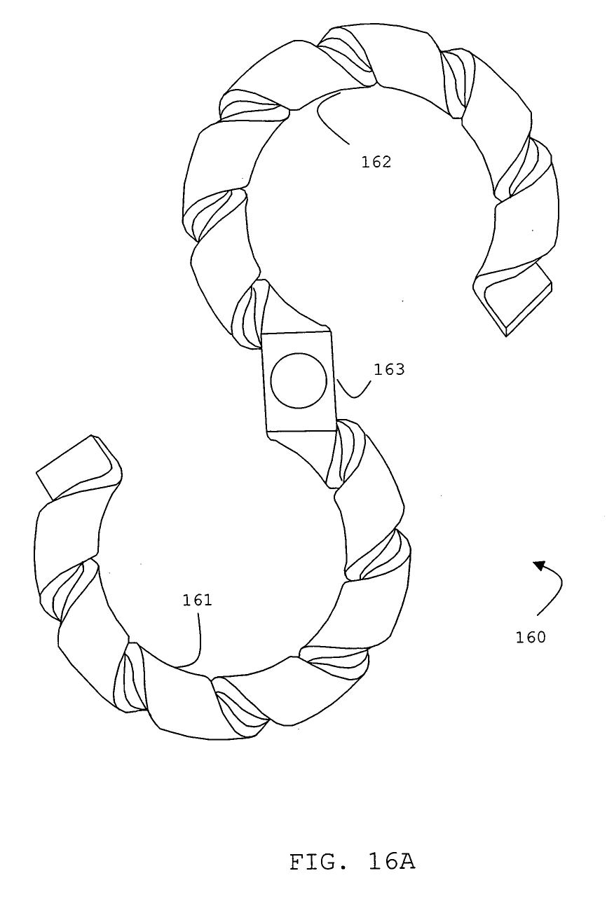

FIG. 15 shows the example of FIG. 14 as drive unit for a center-mounted loudspeaker cone;

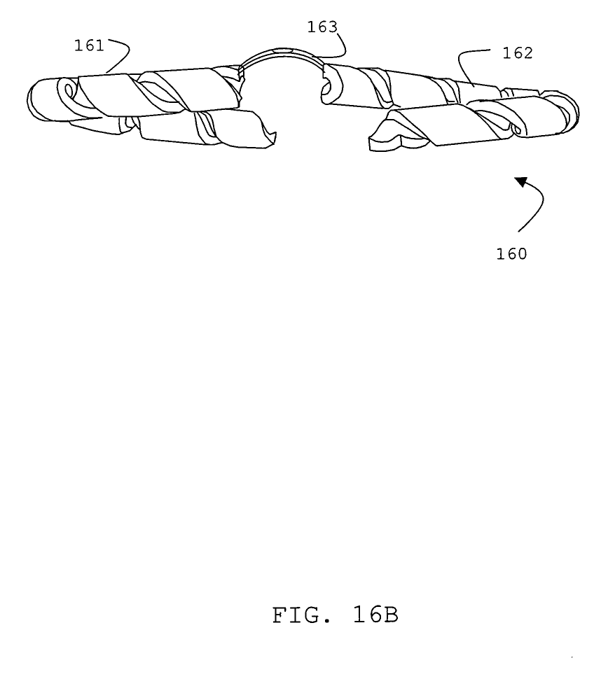

FIGS. 16A, B shows a further example of an S-type actuator in accordance with the present invention;

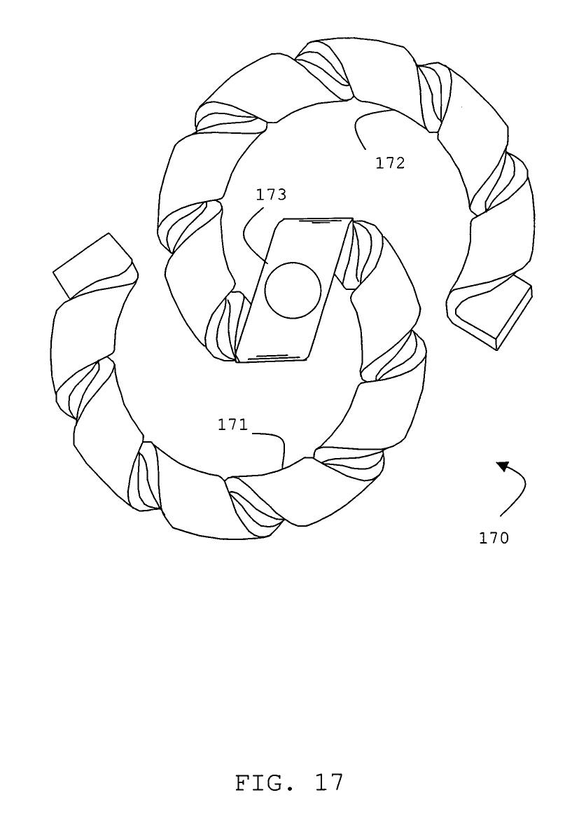

FIG. 17 shows another example of an S-type actuator in accordance with the present invention;

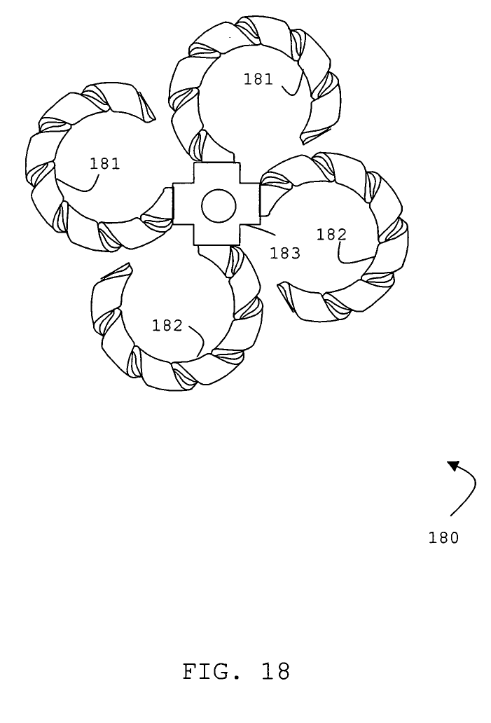

FIG. 18 shows another example of an actuator in accordance with the present invention; and

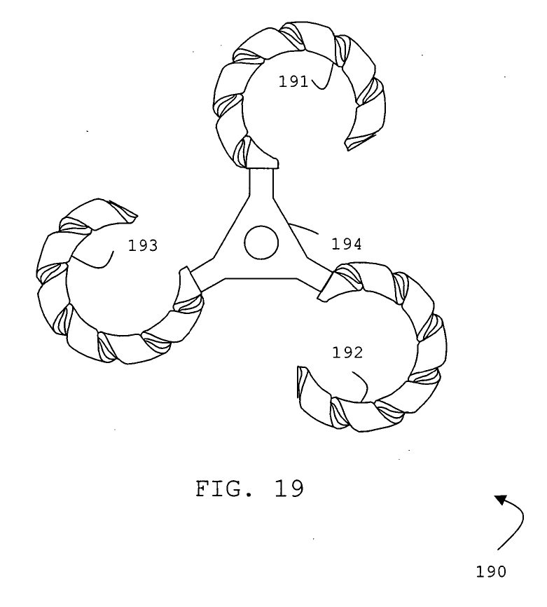

FIG. 19 shows another example of an actuator in accordance with the present invention.

In the hereinafter described embodiments, the described shapes of the various actuators are the normal, permanent shape in the inactive state.

Four different curved actuators 11 of a helical type of embodiment of the present invention are shown in FIGS. 1A-D. In each case, the actuator 11 has a curved portion 12 has a curved portion 12 having a bender construction, for example arranged as a bimorph tape, that extends along and is wound helically around an axis. The curved portion 12 is arranged to bend around the axis of the helix. Thus, on actuation of the actuator 11, the curved portion 12 twists around the axis of the helix. The helix itself is further curved into a secondary curve, for example of about two-thirds of a complete turn. The helix is known as the primary winding or primary helix. The secondary winding could exceed one turn and form a spiral or secondary helix. It is therefore usually referred to as secondary curve or secondary helix. The result of the secondary curve is that, on actuation of the actuator 11, the twist of the curved portion 12 around the axis of the helix causes relative displacement of the ends of the curved portion 12 out of the plane of the secondary curve.

In fact, the actuator 11 is an actuator of the type described in the above-mentioned WO-01/47041 and Sensors and Actuators A 100 (2002), 281-286 which are incorporated herein by reference. In general, any of the features of the construction and/or arrangement of any of the actuators formed from a continuous member which are described and claimed in WO-01/47041 and Sensors and Actuators A 100 (2002), 281-286 could be applied to the curved portion of the present invention.

Whilst the curved portion 12 of the actuator11 is known per se, the present invention facilitates the mounting and contacting of the actuator for industrial production. In the known configurations of this type of complex-shaped actuator, soldering thin wires to the two outer electrodes and the inner electrode of the bimorph tape has provided electrical contacts. Apart from being cumbersome and error prone, this known method does not lend itself readily for mass manufacturing as the soldering operations have to be performed with high accuracy to prevent short circuits and loss of contact.

However, in the actuators 11, the first winding or turn 121 (and/or the last winding 122) of the primary helix is extended into a substantially flat terminal portion 13 which forms a projecting tab.

The direction into which the terminal portion 13 extends may vary. In FIG. 1A, the terminal portion 13 extends essentially tangentially from the first winding 121. To allow a flat mounting on a board, the pitch angle of the terminal portion 13 is essentially equal or less than the pitch angle of the secondary helix. Where, as shown, the pitch angle is zero the terminal tab 13 and the secondary helix are co-planar.

In FIG. 1B the terminal portion 13 again extends tangentially from the first winding 121. It is oriented essentially perpendicular to the plane of the secondary helix or arranged at 90 degrees plus the pitch angle to the plane of the secondary helix.
In FIG. 1C, the terminal portion 13, initially oriented tangentially, includes a bend portion 131 that provides an arbitrary orientation to the remaining portion of the terminal 13.

In FIG. 1D, the terminal portion 13 is edge bent to extend essentially in a direction parallel to the axis of primary helix.

In FIG. 2 a cross-section of the terminal portion 23 is shown. The construction of the terminal portion 23 distal from the end, that is shown on the left hand side of FIG. 2, is a bender construction comprising two layers of electro-active material, preferably piezoelectric material. The hatched portions are electrically conductive and comprise the electrode layers 211, 212, 213 arranged to pole and activate the actuator. This bender construction extends continuously into and along the curved portion 12 of the actuator 13 and provides the bending of the curved portion described above. The bender construction also causes some bending of the terminal portion 23, although the degree of the resulting displacement is relatively small as the length of the terminal portion 23 is significantly less than the length of the curved portion 12, by at least an order of magnitude.

At the end of the terminal portion 23, that is shown on the right hand side of FIG. 2, the terminal portion 23 has, on the same surface 236 as a first outer electrode layer 211, two terminals 232, 233 isolated from each other and from the first outer electrode layer 211. Electrically conductive paths 234, 235 extending through openings punched or drilled through the terminal connect the two terminals 232, 233 to the inner electrode 212 and the second outer electrode 213, respectively. As a result, electrical connection to all the electrodes 211, 212, 213 of the actuator 11 can be made by contact on a single face 236 of the terminal 23.

A difficulty to be overcome when producing curved ceramic structures with projecting tabs lies in the plasticity of the green tape used as an intermediate in the manufacturing process of complex ceramic actuators.

To fabricate the actuators of FIGS. 1A-D, a commercial piezoelectric lead zirconate titanate (PZT) powder can be used as the strating material, for example TRS 600 (TRS Ceramics Penn., USA). The powder is mixed with polyvinyl butyral binder and cyclohexanone on a twin-roll mill until a uniform 1 mm thick sheet is obtained. This material is then rolled up and extruded to obtain a uniformly thick and defect-free sheet. The sheet is then calendered to the required thickness being half that of the final bimorph tape. The bimorph structure is produced by screen printing the tape with conductive ink such as platinum ink. Two or more of these tapes can then be laminated to form bimorphs. Strips of suitable width are cut from the tape and wound on to a first cylindrical former the outer diameter of which determines the inner diameter of the primary helix. The strips are then placed into a second former that determines the secondary helix radius.

The second former has a shallow groove or a narrow cut into which the end of the laminated strip is placed. The dimensions and orientation of the shallow groove or narrow cut, together with the length of the ceramic strip placed into it, determine the orientation and length of the final terminal tab.

The assembled structure is then dried to remove solvents and plastizers. At this stage support for the projecting terminal may not be necessary as the structure becomes sufficiently rigid to not collapse under its own weight. The actuator is then fired. Following a slow binder removal stage at up to 600 degrees C., the material is sintered at 1200 degrees C. for 1 hour.

Soldered electrode contacts are made to the outer two electrodes and the single inner electrode. The material is poled in a heated silicone oil bath at 120 degrees C. and 2.5 kVmm-1 for 10 minutes. After cleaning, the outer two electrodes are joined together to form a single external electrode which, together with the central electrode, is used to generate the required opposing actuation fields.

An example of a packaged actuator manufactured in accordance with the above steps is shown in FIG. 3. The curved actuator 31 is mounted over an opening of a board 32, suspended only at the projecting tab or terminal 33. The tab is connected to the board at several soldering points 34. The assembled structure can be mounted onto larger structures, such as a PCB board, via three connection pins 35.

An actuator 40 of the Q-type is shown in FIG. 4A in perspective view. The actuator 40 has a substantially uniform shape in a first direction (perpendicular to the line A-B in FIG. 4A). The actuator 40 includes a first curved section 41 having a cross-section which is substantially a section of a circle. Thus the first section 41 is curved around a nominal axis which is the centre of the circle, although this precise shape is not essential and other cross-sections curving around a nominal axis would be possible. The actuator 40 is arranged to bend, on actuation around the nominal axis.

The actuator 40 extends from the first curved section 41 through a second curved section 42 of opposite curvature from the first curved section 41 into an essentially flat section 43 extending away from the nominal axis of the first curved section 41, preferably radially.

The actuator 40 has bender construction extending continuously along the first curved section 41, the second curved section 42and the flat section 43. The bender construction may be the same bender construction as the helical type of embodiment described above, in particular with the flat section 43 arranged as shown in FIG. 3.

The actuator 40 may be a multi-layered ceramic tape 401 with layers of ceramic PZT, or other electro-active material, separated by layers of electrodes. The numbers of such layers are determined by the manufacturing process and can range from two ceramic (PZT) layers to more than ten.

The tape can be produced in accordance with well known manufacturing techniques, as described above. In its green state, it is then cut and pressed onto a suitable former to give it the form shown in FIG. 4A. Then the tape is burned out and sintered at high temperatures (600 to 1200 degrees Celsius). Outer electrodes may be applied after the sintering. After a poling step the actuator is ready to be mounted onto a chassis. These manufacturing steps are known per se and are regarded to be well within the scope of person skilled in the art.

A schematic cross-section through the actuator 40 of FIG. 4A along the line AB is shown in FIG. 4B. The first curved section 41 is convex, whilst the second section 43 is essentially flat. Between the two sections, there is a portion 42 where the curvature changes from convex to concave. The convex and concave portions of the actuator are indicated by dashed circles reflecting their respective main radii R1 and R2 of curvature. The multi-layered tape making up the actuator acts essentially as a bender with different portions moving in different directions as indicated by arrows in FIG. 4B. As the first curved section 41 moves essentially circumferentially, the flat portion 43 and the intermediate concave portion 42 move upwards. The combined motion of the distal end 411 of the actuator is indicated by arrow 44. It is an essentially vertical movement with lesser components of the motion in undesired tangential directions compared to known actuators such as the C-shaped actuator of WO-03/001841. The rotational displacement of the known C-shaped actuator of WO-03/001841 is similar to the motion of the first curved section 41, however in the case of the novel actuator 40 it is partly cancelled by the concave section 42, resulting in an improved or “purer” vertical displacement of the distal end 411. The flat portion 43 can be readily mounted on to a flat surface and to electrical terminals to connect the actuator to an electronic drive circuit and power supply.

The example of FIG. 5 shows a variant of the previous example modified in that the flat section 53 includes two tabs or lead-outs 531. In other words, a rectangular section is cut out of the flat portion 53, thus reducing the amount of active material necessary to implement the actuator 50 while at the same time preserving the advantageous properties of the novel actuator design as described herein. Thus, other elements 51, 52 of the actuator and their motion are essentially identical to those illustrated in FIG. 4B above.

The two tabs 531 provide a sufficiently large area to mount the actuator onto a flat surface and electrical terminals to connect the actuator to an electronic drive circuit and power supply.

For some applications, it may be useful and advantageous to terminate the distal end of the actuator with a second flat portion. This second flat portion, though not contributing significantly to the displacement, could facilitate the mounting of the distal (moving) end of the actuator onto a movable object such as a loudspeaker diaphragm.

In FIG. 6 such an actuator 60 is shown. In addition to the convex section 61, the flat section 63 and the intermediate portion 62 shared with the above examples, the actuator 60 has a flat portion 64 at it distal end.

In FIG. 7, the actuator of FIG. 4 is shown used as a drive unit 70 to drive a rectangular diaphragm 74 within the housing 75 of a mobile device such as a mobile phone. The diaphragm material is Perspex™ (poly methylene methacrylate). The diaphragm 74 rests within a recess of the housing so as to be mounted flush with the outer surface of the housing 75.

The gap between the housing 75 and the diaphragm 74 is sealed off by means of a compliant gasket 76 shown in FIG. 7B, which is a cross-section of the perspective view of FIG. 7A along the line AB. The gasket 76 prevents the entry of dust or humidity. It is made of Poron™, a cellular urethane based sealing material. The actuator 70 bridges the gap between the housing 75 and the diaphragm 74 at one short side of the rectangular diaphragm. The flat portion 73 of the actuator is mounted onto the housing while the curved portion 71 spans the sealed gap. The distal end 711 of the actuator is glued onto the diaphragm material 74.

When an operating voltage is applied to the actuator 70, the displacement drives the edge of the diaphragm 74 which in turn generates audible sound.

The larger contact area between the actuator 70 and the housing 75 together with the improved displacement of the actuator generate a higher sound level and an improved performance of the device as a loudspeaker compared to known devices such as described in WO-03/001841. As such the actuator 70 is suitable for driving a loudspeaker in a portable electronic device such as a mobile telephone, a personal digital assistant or a laptop computer.

An actuator 80 of the U-type is shown in perspective view in FIG. 8A, in cross-sectional view in FIG. 8C and in top view of the bottom face in FIG. 8B. The actuator 80 includes a convex curved or arcuate middle section 81. Both ends of the middle section 81 extend continuously in tangential direction into two essentially flat sections 82, 83. The actuator 80 has a bender construction that extends continuously along one flat section 82, the curved section 80 and the other flat section 83. This bender construction comprises two layers of electro-active material, preferably piezoelectric material. For example, the actuator 80 may be manufactured from multi-layered ceramic tape 801 with layers of ceramic PZT separated by layers of electrodes. The outer (visible) electrodes 802 are split at the transition zone between different section by gaps 803. By means of this arrangement of split electrodes and the poling of the electro-active material which will be described below, the flat sections 82, 83 are each arranged, on actuation, to bend in a sense opposite from the curved section 80.

The flat section 83 forming the bottom face of the actuator carries further contact points. The contact points 804 provide conductive channels (via-fills) 805 to the center electrode 806 and the opposite outer electrode 802, respectively. Thus the contact points 804 and the electrode 802 on the same surface as the contact points 804 act as terminals for electrical connection to the electrodes. Placing the contact points 804 on the bottom face is advantageous when using surface mounting to mount the actuator on supporting structures such as PCB boards (see FIG. 10).

In FIG. 9 there is illustrated the deformation of the U-type actuator 90 upon activation by an appropriate voltage applied to the electrodes. The actuator without activation is drawn using solid lines and dashed lines are used to depict the energized actuator. It should be noted that the deformation is drawn out of scale.

Upon activation, the ends of the c-shaped center section 91 perform a rotational movement with a slight contraction around its center of curvature as indicated by the arrows 94, 95. The extended straight sections 92, 93 bend as conventional benders. The distal ends 921, 931 of the actuator perform a very good approximation of a linear motion in a vertical direction as indicated by the arrow 96.

In FIG. 10, the actuator of FIG. 8 is shown used as a drive unit 100 to drive a rectangular diaphragm 104 within the housing 105 of a mobile device. The diaphragm is made of transparent polycarbonate. It rests within a recess of the housing so as to be mounted flush with its outer surface.

The gap between the housing 105 and the diaphragm 104 is sealed off by means of a compliant gasket 106. The gasket 106 prevents the entry of dust or humidity. It is made of Poron™, a cellular urethane based sealing material.

The actuator 100 is surface mounted with a first distal end 107 of the bottom straight section onto a PCB board 101 that carries drive electronics, power supply and other electronic circuitry. The end 108 of the top straight section of the actuator 100 is connected to an edge of the diaphragm 104 via a spacer element 102. The connection is capable of transmitting a force such that in operation the vertical movement of the actuator 100 drives the edge of the diaphragm 104 which in turn generates audible sound.

The effective length of the straight sections is in part determined by the length over which these sections are mounted or connected to a spacer element or support. These parts of the sections become too stiff to deform as a bender. When considering the active length of a section these parts have to be discounted.

Compared to known devices such as described in WO-03/001841, the novel configuration provides an improved sound quality.

The novel actuator can be manufactured from ceramic tape material made in accordance with known techniques as described above. The electrodes are screen printed onto the sheet using platinum or silver ink. A specific electrode layout may be used that facilitates the manufacturing and mounting of the novel actuators. This layout is shown in FIG. 11, which depicts the outer, center and inner electrode layer of an actuator with two PZT layers (as shown in FIG. 8).

The outer electrode 111 and the inner electrode 113, which on the actuator will both form outer visible electrodes, are split by lines 114 into sections which correspond to the sections to be seen on the finished actuator. The center electrode 112 is continuous but includes smaller blank areas 115. Cross-layer electrical contacts are made at a later stage either through (using a via-fill) or across the outer edges of the areas 115(using conductive ink or solder). With the electrode pattern and blank areas it is possible to connect electrodes such that an electrically conducting path is established between the end sections of one discontinuous electrode 111 to the middle section of the other discontinuous electrode 113 bypassing the continuous electrode 112.

Hence, in the finished actuator as shown in FIG. 8, the end sections of the outer visible electrode lie on the same potential as the middle section of the inner visible electrode and the end sections of the inner visible electrode lie on the same potential as the middle section of the outer visible electrode. In this configuration, the center electrode is not connected to any section of the outer electrodes.

Two or more printed sheets are then stacked to form a final bimorph tape. The bimorph (“green”) tape is still plastically deformable.

A further processing step towards the novel actuator is shown in FIG. 12. In the forming step of FIG. 12, the green tape 120 is placed between the moving part 123 and stationary part 124 of a former or mold (FIG. 12A). The moving part 123 is then pressed downwards into the opening of the stationary part 124 thereby forcing the tape into the desired shape (FIG. 12B). In its final position (FIG. 12C), the moving part 124 has pushed the tape fully into the U-shaped mold.

It is worth noticing that the outer contour of the moving part 123 matches the inner contour of the stationary part 124 along the bottom section of the mold essentially corresponding to the curved center section of the finished actuator. However above this section the cross-section of the moving part tapers away from the walls of the mold 124, thus facilitating the removal of the moving part without pushing the tape out of its final position or form.

The tape can be left drying in the former and then removed from it. Then the tape is burned out and sintered at high temperatures (600 to 1200 degrees Celsius). Outer electrodes may be applied after the sintering step.

In a poling step the straight sections (as referred to in FIG. 8) are poled in a direction opposite to the poling direction in the center section.

After the poling the actuator is ready to be mounted onto a support and a driving voltage can be applied for example to the center electrode.

A known actuator 130 of the type described in the above-mentioned WO-0147041 and Sensors and Actuators A 100 (2002), 281-286 is shown in FIG. 13. As previously discussed, the known actuator 130 comprises an electro-active member 132 having a bender construction, eg a bimorph tape 131, that extends along and is curved helically around an axis 133 referred to as the minor axis 133. The minor axis 133 is nominal and for illustration is shown as a dashed line in FIG. 13. The minor axis 133 is curved, for example along a section of a circle in FIG. 13. The electro-active member 132 is arranged to bend, on activation, around the minor axis 133 and hence to twist around the minor axis 133 concomitantly.

The minor axis is itself curved, for example in FIG. 13 along a section of a circle amounting to about three quarters of a complete turn. The axis 134 of this secondary curve is referred to as the major axis 134and shown as a small dashed circle with a central solid point again to facilitate description and illustration. The curve around the minor axis 133 may be referred to as the primary winding or primary helix. The curve around the major axis 134 may be referred to as the secondary winding, and could exceed one turn and form a spiral or secondary helix.

As a result of the curve around the major axis 134, the twisting on activation described just above is concomitant with relative displacement of the two ends 136 and 137 of the electro-active member 132 out of the plane of the curve. In particular, the distal free end 136 moves parallel to the major axis 134 and thus perpendicular to the paper plane assuming that the base-mounted or near end 137 is fixed to an immobile support 135.

As the displacement of the distal end 136 represents a motion caused by summing infinitesimal rotational and bending displacements of the tape 131 around the minor axis 133, it is not surprising that its motion is not strictly linear in the sense of moving in a straight line but comprises small rotational components and unwanted (off-axis) translational. These deviations from a straight line are acceptable in many applications and can be limited by further mechanical constraints such as bearings.

Embodiments of the S-type will now be described. These embodiments improve the straight-line motion of the known actuator 130 of FIG. 13 by coupling one or more of the known actuators as balanced pairs, triplets, quadruplets etc. of essentially identical actuator sections into a configuration arranged such that at least some of the non-linearities of the known actuator are balanced out and hence reduced or eliminated from the motion of the free end of the combined actuator.

As the piezo-ceramic tape undergoes many manufacturing steps from the formulation of the base powder including tape casting, electroding, winding, firing and poling, all of which could potentially introduce variations and inhomogeneity between single actuators, it is advantageous to manufacture the balanced sets of actuator sections from a single continuous tape. Thus in a first example of an actuator in accordance with the present invention, a balanced pair is formed from a continuous tape of electro-active ceramic material.

An actuator 140 of the S-type 140 of FIG. 14 comprises an electro-active member 141 having a bender construction, eg a bimorph tape, that extends along and is curved helically around a minor axis which is curved to have two sections 142, 143. In each section 142, 143, the minor axis has opposite curvature such that there is rotational symmetry about the point between the two sections 142, 143. Thus, the sections 142, 143 are coupled by a small joint section 144 which is a portion of the electro-active member at which the curvature changes. Each section 142, 143 extends substantially along a section of a circle. This is preferred as being the best shape for balanced operation, as described in more detail below, although other curves would be sufficient. Each section 142, 143 has the same construction as the known actuator 130 described above except that the electro-active member 141 is continuous between the two sections 142, 143. In general, any of the features of the construction and/or arrangement of any of the actuators formed from a continuous member which are described and claimed in WO-01/47041 and Sensors and Actuators A 100 (2002), 281-286, which are incorporated herein by reference, could be applied to the sections 142, 143 of the electro-active member.

Both sections 142, 143 include a curved portion of bimorph tape 141 that is wound helically around a first axis that is referred to as minor axis. The helically wound portion is further coiled into a secondary winding of about two-thirds of a complete turn.

However, the first section 142 is bent inwardly thus giving the first section concave curvature. In the joint section 144 the curvature is reduced and approaches zero before the minor axis bends outwardly in the part of the helically wound tape that forms the second section 143 of the actuator.

The device of FIG. 14 exhibits a symmetry about the joint section that could be described as being point-symmetric. It is therefore arbitrary to define the first section as concave and the second section as convex. It is however important to notice that the curvature changes its sign or orientation from one section to the other. A sign or orientation can be assigned to a curvature by use of the so-called right hand rule, following which, as the fingers are curled as the device, the thumb defines its orientation. Applying this rule at each point of the device from one end to the other the orientation flips after passing through the joint section. The major axes 145, 146 of the first and second sections 142, 143, respectively, are illustrated in FIG. 14, with a point in a dashed circle marking an orientation out of the paper plane and cross in a dashed circle marking the opposite orientation.

The number of primary windings is six for each section of the actuator. The thickness of the tape is 1.2 mm. Its width is 5.5 mm. The outer diameter of the primary helix is 5 mm and the outer diameter of the secondary helix, which is a 0.75 turn, is 30 mm. Each section includes an additional half turn that makes up the joint section 144 of the actuator. The tape has a linear piezo constant of 135 pC/N. Such a bimorph tape device can be driven by a 600 Volt amplitude signal to a maximal displacement of 0.5 mm. In a device with 8 active layers of piezoelectric material the same displacement can be achieved with a drive voltage of 150 V.

The flat plateau part of the joint section 144 is located at a circumferentially opposite position (with regard to the circumference of the minor helix) to the end parts of both the first and second section. In addition, at the end of the single curved portion constituted by the two sections 142, 143, the electro-active element 140 extends continuously into two flat portions 147.

The electro-active member 141 has bender construction extending continuously along the the curved portion constituted by the two sections 142, 143 and the two flat portions 147. The bender construction may be the same bender construction as the helical type of embodiment described above, in particular arranged as shown in FIG. 3. One of the flat portions 147 has the arrangement of terminals for electrical connection to the electrode layers shown in FIG. 3 and described above.

This arrangement of the joint section 144 and the flat portions 147 facilitates the mounting of objects to be driven or actuated by the actuator 140.

As a result of the curvature of the electro-active member 141, the twisting of the sections 142, 143 which occurs on activation is concomitant with relative displacement of the joint section 144 with respect to the opposite end portions 147 of the two curved sections 142, 143. In use the end portions 147 are coupled to one object and the joint section 144 is coupled to another object to drive relative displacement of the two objects, as for example in the following arrangement shown in FIG. 15 which illustrates a loudspeaker configuration.

In FIG. 15, the actuator 140 of FIG. 14 is shown driving an oval shaped cone 150. The cone is the sound-generating element or the diaphragm of a loudspeaker system. The flange 151 of the cone is connected to the mounting plate 155 of the actuator through four struts 152. The actuator 140 rests on two flat mounting posts 156 (only one is shown) above the mounting plate 155. At its centre, the joint section 144 and the apex 153 of the cone 150 are connected. Alternatively, the mounting points could be reversed, using the central joint section to mount the actuator onto the immobile base and connecting the object to be moved to one or both ends of the actuator.

In operation, the device of FIG. 15 is driven with a drive voltage of up to ±600 V peak voltage modulated with frequencies within the acoustic frequency range of 20 Hz to 20 kHz.

The actuators of FIGS. 14 or 15 can be made using the manufacturing steps known for producing super-helical devices (as shown in FIG. 13) and described above. For S-type actuators, the second former has an S-shaped groove having a depth in the order of the diameter of the primary helix.

In other examples of the invention the novel actuator 160 is assembled by joining two actuators as known per se and illustrated in FIG. 13 through a joint element or hub of hetero (non-piezoelectric) material such as metal or plastics. In FIG. 16, the joint element is a steel flexure 163. The flexure is designed to be stiff in lateral directions while being more flexible in the vertical (out of the paper plane of FIG. 16A). The actuator further includes two three-quarter turn super-helical actuators 161, 162 bonded at their respective distal ends by a glue or adhesive or other suitable attaching technique to the joint element 163.

In this configuration the actuator can exhibit a larger displacement with albeit less force than the example described above.

In FIG. 16B the device 160 is shown with both actuator sections 161, 162 bent upwards. The displacement causes the joint element 163 to flex. In applications where such a flexing action is not desired, the flexure could be replaced with a stiff bridge element with or without hinges at the joining lines with the two actuators, or with a single hinge at the center of the joining piece.

The configuration of FIG. 16 can be extended to multi-turn sections where each actuator section has several turns around its major axis before being joined.

Alternatively, the two actuator sections may be nested. In FIG. 17 the free ends of each section 171, 172 are located within the inner circumference of the other section, thus providing a more compact configuration of the novel actuator. The elements and structures in FIG. 17 are otherwise identical to those of FIG. 16 and are, hence, not further described.

In another variant, there are more than two actuator sections joined in a manner that maintains the required balance between the undesired displacements. A possible configuration of such an actuator is shown in FIG. 18. The actuator combines two balanced pairs of actuator sections 181, 182 joined by a central cross-shaped hub or joint element 183. The elements and structures in FIG. 18 are otherwise identical to those of FIG. 16 and are, hence, not further described.

In another variant, there are three actuator sections joined in a manner that maintains the required balance between the undesired displacements. A possible configuration of such an actuator is shown in FIG. 19. The actuator 190 combines three actuator sections 191, 192, 193 joined by a central cross-shaped hub or joint element 194. The desired cancellation of non-straight-line motions will occur so long as the actuator sections are placed symmetrically about the central joining element, in this example at radial positions each separated by 120 degrees.

It will be apparent that more complex groups of balanced actuator section can be arranged to form the novel actuator. And several groups of actuators may be arranged in differently oriented planes such that the direction of the straight-line motion is the (vector) sum of the motion generated by the actuator sections within each group.

1. An electro-active actuator having a bender construction comprising layers of electro-active material and electrode layers for activation of the electro-active material, the layers of electro-active material being shaped to extend continuously along at least one curved portion and at least one substantially flat portion arranged with electrical terminals for electrical connection to the electrode layers.

2. The electro-active actuator of claim 1, wherein the curved portion forms a helix arranged, on actuation, to bend around the axis of the helix.

3. The electro-active actuator of claim 2, wherein the helix formed by the curved portion is itself curved.

4. The electro-active actuator of claim 1, wherein the flat portion extends tangentially from the curved portion.

5. The electro-active actuator of claim 1, wherein the flat portion has a length equal to or exceeding an outer diameter of the curved portion.

6. The electro-active actuator of claim 1, wherein the electrical terminals are located on the same face of the flat portion.

7. The electro-active actuator of claim 1, wherein the electro-active material is a ceramic material.

8. The electro-active actuator of claim 1, wherein the substantially flat portion is arranged as a projecting tab.

9. (canceled)

10. A method of manufacturing an electro-active actuator having a bender construction comprising layers of electro-active material and electrode layers for activation of the electro-active material, the layers of electro-active material being shaped to extend continuously along at least one curved portion and at least one substantially flat portion arranged with electrical terminals for electrical connection to the electrode layers, the method comprising:
preparing a ceramic tape in a green state;
placing said tape into a former having a section to support said flat portion and maintain the orientation of said flat portion with respect to the permanently curved portion of the actuator; and
drying said tape within said former to reduce the plasticity of said tape.

11. The electro-active actuator of claim 1, comprising a single curved portion curving around an axis and arranged, on actuation, to bend around the axis, and at least one flat portion extending away from the axis.

12. The electro-active actuator of claim 11, wherein the curved portion has a substantially uniform shape parallel to the axis.

13. The electro-active actuator of claim 11, wherein the flat portion extends radially away from the axis.

14. The electro-active actuator of claim 11, wherein the curved portion has a cross-section perpendicular to the axis which is substantially a section of a circle.

15. The electro-active actuator of claim 11, wherein the curved portion has a first part curving around said axis and a second part extending from the first part to said straight portion and having a curvature of opposite sign from said first curved portion.

16. The electro-active actuator of claim 11, wherein the electroactive material is a ceramic material.

17.-20. (canceled)

21. A loudspeaker for audible sound comprising a sound emitting element mounted onto a support structure and at least one actuator as claimed in claim 11 being mounted at a proximate edge onto said sound emitting element and a distal edge onto said support structure.

22. The loudspeaker of claim 21 having a compliant sealing element or elements around the edges of the sound-emitting element.

23. The loudspeaker of claim 21, wherein the second flat section with the distal edge is mounted onto a part of the support structure while the first curved section with the proximate edge is mounted onto the sound-emitting element such that said curved section bridges a gap between said sound emitting element and said support structure.

24. The loudspeaker of claim 21, wherein the support structure and the sound generating element are parts of the outer shell of a portable data handling or communication device.

25. The loudspeaker of claim 21, wherein the second flat section extends in a longitudinal direction into a rectangular shape.

26. The loudspeaker of claim 21, wherein the second flat section terminates as two or more flat portions.

27. The electro-active actuator of claim 1, comprising a single curved portion and two flat portions extending tangentially from opposite ends of the curved portion, at least one of which is arranged with said electrical terminals for electrical connection to the electrode layers.

28. The electro-active actuator of claim 27, wherein the two flat portions are substantially parallel to each other.

29. The electro-active actuator of claim 27, wherein the straight portions are each arranged, on actuation, to bend in a sense opposite from the curved portion.

30. The electro-active actuator of claim 27, wherein the straight portions are each poled in a direction opposite from the direction in which the curved portion is poled.

31.-32. (canceled)

33. A loudspeaker for audible sound comprising a sound emitting element mounted onto a support structure and at least actuator as claimed in claim 27 being connected to said sound emitting element and a support, wherein the sound emitting element is connected to an end portion of one of the flat portions and the actuator is mounted with an end portion of the other flat portion connected to the support.

34. The loudspeaker of claim 33 having a compliant sealing element or elements around the edges of the sound-emitting element.

35. The loudspeaker of claim 33, wherein sound emitting element is a flat or slightly curved transparent panel.

36. The loudspeaker of claim 33, wherein the support structure and the sound generating element are parts of the outer shell of a portable data handling or communication device.

37. A method of manufacturing an electro-active actuator having a bender construction comprising layers of electro-active material and electrode layers for activation of the electro-active material, the layers of electro-active material being shaped to extend continuously along a single curved portion and two substantially flat portions extending tangentially from opposite ends of the curved portion, at least one of the flat portions being arranged with said electrical terminals for electrical connection to the electrode layers, the method comprising:
manufacturing deformable sheets of pre-cursor material;
applying a first, a second and a third electrode onto the sheets;
stacking said sheets such that at least one first, second and third electrode overlay to form a layer of bimorph tape;
pressing the bimorph tape into the shape of the actuator; and
sintering the shaped tape,
wherein two of the three electrodes have gaps at locations corresponding to areas between adjacent sections of the actuator and one of the three electrode is continuous across the areas.

38. The method of claim 37, further comprising the step of poling the straight portions of the actuator oppositely to the curved portions.

39. The electro-active actuator of claim 1, wherein the curved portion forms a helix arranged, on actuation, to bend around the axis of the helix, which helix is itself curved to have two sections of opposite curvature with rotational symmetry about the point between the two sections.

40. The electro-active actuator of claim 39, comprising a single curved portion.

41. The electro-active actuator of claim 40, including a said flat portion arranged with electrical terminals for electrical connection to the electrode layers at one end of the curved portion.

42. The electro-active actuator of claim 41, including a further substantially flat portion at the other end of the curved portion.

43. The electro-active actuator of claim 42, wherein said further flat portion at the other end of the curved portion is arranged with electrical terminals for electrical connection to the electrode layers.

44. The electro-active actuator of claim 42, wherein the actuator is mounted to a first object at said point between the two sections and to a second object by said first mentioned flat portion and said further flat portion.

45. The electro-active actuator of claim 39, wherein said two sections of opposite curvature are substantially sections of a circle.

46. An electro-active device having a continuous electro-active member extending along a minor axis which is curved, the continuous electro-active member curving around the minor axis and arranged with electrodes to bend, on activation, around the minor axis, thereby to twist around the minor axis concomitantly with relative displacement of portions of the device out of the plane of the curve, wherein the minor axis follows a curve having two sections of opposite curvature with rotational symmetry about the point between the two sections.

47. The electro-active actuator of claim 46, wherein the continuous electro-active member curves around the minor axis in a helix.

48. The electro-active actuator of claim 46, wherein the minor axis follows a curve having a single change in curvature at said point between the two sections.

49. The electro-active actuator of any one of claim 46, wherein the actuator is mounted to a first object at said point between the two sections and to a second object at the opposite ends of said two sections.

50. The electro-active actuator of claim 46, wherein said two sections of opposite curvature are substantially sections of a circle.

51. An electro-active actuator adapted to move objects in a straight line, said actuator having at least one group of coupled actuator sections with each of said sections having a structure of electro-active material extending around a minor axis which is permanently curved and wherein the structure of electro-active material includes successive electro-active portions having electrodes to bend, when activated, around the minor axis, and said sections being coupled by a joint element and arranged in a rotational symmetry about said joint element.

52. The electro-active actuator of claim 51, wherein the actuator sections within each group move, when activated, parallel to one another while balancing out motions in other directions.

53. The electro-active actuator of claim 51, wherein the actuator sections within each group are essentially identical.

54. The electro-active actuator of claim 51, wherein each section comprises a continuous electro-active element extending along and curving around the minor axis.

55. The electro-active actuator of claim 54 wherein the continuous electro-active element curves around the minor axis as a helix.

56. The electro-active actuator of claim 51, having at least two actuator sections of opposite curvature coupled by the joint section.

57. The electro-active actuator of claim 56, wherein the two actuator sections of opposite curvature are formed from one continuous tape of electro-active ceramic material.

58. The electro-active actuator of claim 57, wherein the two actuator sections and the joint section are formed from one continuous tape of electro-active ceramic material.

59. The electro-active actuator of claim 51, wherein the joint section comprises a hetero material.

60. The electro-active actuator of claim 59, wherein the joint section is adapted to be relatively stiff in all but one direction.

61. The electro-active actuator of claim 51, wherein all actuator sections within one group are adapted to receive essentially identical activation signals.

62. The electro-active actuator of claim 1, wherein the layers of electro-active material comprises sintered electro-active material.

63. The electro-active actuator of claim 1, comprising a single curved portion and either a single flat portion at one end of the curved portion or a respective flat portion at each end of the curved portion.
